(19) United States
(12) Patent Application Publication
(10) Pub. No.: US 2013/0059431 A1
(43) Pub. Date: Mar. 7, 2013

(54) DEVICE AND METHOD FOR SUBSTRATE PROCESSING

(71) Applicants: Jessica Hartwich, Sauerlach (DE); Franz Karg, Muenchen (DE)

(72) Inventors: Jessica Hartwich, Sauerlach (DE); Franz Karg, Muenchen (DE)

(73) Assignee: SAINT-GOBAIN GLASS FRANCE, COURBEVOIE (FR)

(21) Appl. No.: 13/581,982

(22) PCT Filed: Feb. 22, 2011
(86) PCT No.: PCT/EP11/52575

§ 371 Date: Nov. 2, 2012

(30) Foreign Application Priority Data
Mar. 1, 2010 (EP) 10154992.1

(51) Int. Cl. C23C 16/458; H01L 21/36

(52) U.S. Cl. 438/479; 118/500; 118/728; 427/248.1; 427/255.5; 257/E21.461

(57) ABSTRACT

The present invention relates to a device for processing substrates in a processing system with at least one process tool disposed in at least one process area, which tool has two substrate levels disposed opposite each other in the process area, which are aligned at least approximately vertical, wherein the device is adapted to process at least two substrates at the same time in the process area by means of the process tool, wherein the substrates can be disposed in the substrate levels such that coatings of the substrates face each other and, at least during processing, a quasi-closed process space is formed between the substrates. It further relates to a method for processing coated substrates in a processing system, wherein the substrates have coatings and the substrates are each disposed opposite each other such that the coatings of the substrates face each other and, at least during processing, a quasi-closed process space is formed between the substrates.

The present invention relates to a device and a method for substrate processing in a processing system with at least one process tool disposed in a process area.

Such processing is undertaken, in particular, in the production of semiconductor components and can, consist, among other things, in coating, structuring, tempering, or the like. Especially in the processing of glass substrates with passive and active components (for example, for architectural glazing, for heat reflection out of the interior of a building, for displays, thin-film solar cells, such as CIS/CIGS thin-film solar cells, or the like), coatings and temperature treatments play a significant role. If the coating contains a volatile component (such as, organic compounds, selenium, sulfur, or the like), the coating process, but especially the temperature treatment, results in a considerable loss of volatile components to the environment (such as, the walls of the coating chamber). This results in an uncontrolled shift in the stoichiometry of the coating and/or high additional costs for providing a necessary excess of the volatile components.

In principle, these conditions also apply to the processing of a large number of other substrate materials, such as metal plates, glass ceramic, ceramic, and plastics.

For control of the stoichiometry while at the same time reducing costs for the necessary excess of the volatile components, a temporary process box was proposed in WO 2009/135685. Using this process box, the process space in which the substrate is processed is significantly reduced such that the generation of the necessary partial pressure on volatile components has to be provided for only a substantially smaller amount of the volatile components, which means the costs can be significantly reduced.

The object of the present invention is to further reduce these costs and at the same time to enable homogeneous processing of the substrates or of the coatings on the substrates. This object is accomplished according to the invention by means of a device and a method for processing substrates with the characteristics of the independent claims. Advantageous improvements are reported in the subclaims.

The device according to the invention for processing substrates, in particular coated substrates, in a processing system, preferably a vacuum treatment system, with at least one process tool disposed in at least one process area, in particular a thermal evaporator device, a sputtering device, preferably a rotatable cylinder magnetron sputtering device, a structuring device, a heating device, or the like, is distinguished in that the device has two substrate levels disposed opposite each other in the process area, which are aligned substantially vertical, such that the device is adapted to process at least two substrates at the same time in the process area by means of the process tool, wherein the substrates can be disposed in the substrate levels, wherein the substrate levels are preferably aligned in parallel relative to their vertical components. The substrates can be aligned in the substrate levels such that coatings of substrates face each other and, at least during processing, a quasi-closed process space is formed between the substrates. In a possible embodiment of the device according to invention, a frame gas-tightly delimiting the process space is disposed between the substrates to form a closed process space. Thus, the device is implemented such that the substrates disposed at a certain distance from each other form a substantially closed or quasi-closed process space.

In the context of the present invention, the expression “quasi-closed” describes a process space that is open on the edge, but wherein at least during the period of the processing of the multilayer bodies virtually no gas exchange occurs between the process space and its surroundings, such that no significant change of the process conditions occurs in the process space, since edge effects related to a gas exchange with the surroundings are negligible. In addition, a barrier gas-tightly sealing the process space or a frame gas-tightly surrounding the process space can be provided.

The substrates can be disposed such that they have a distance between them such that a gas exchange barrier or a pressure balance resistance is formed between the process space open to the surroundings and the external surroundings, which prevents vaporizing layer components, process gases, or process reaction gases from passing over into the external surroundings in uncontrolled quantities. This can be achieved by an appropriate selection of the (non-zero) distance between the surfaces to be processed or layers of the substrates opposite each other, which depends on the volume of the process space, the mean free path of the gas particles, or the respective partial pressures of the gases in the process space. For example, a (non-zero) distance between the layers of the substrates to be processed opposite each other is less than 50 mm, preferably less than 10 mm, particularly preferably 1 to 8 mm, and can, with very thin substrates (e.g., films) even be less than 1 mm. These values are based on substrates whose surfaces to be processed have, in each case, for example, a size in the range from 100 cm² to 200000 cm².

Advantageously, the device is implemented such that it is accomplished by means of the distance between the layers of the substrates opposite each other to be processed that a loss of mass of gases in the process space, for example, chalcogen components (S, Se), which, for example, arise by means of the heating process (vaporization and out-diffusion) is less than 50%, preferably less than 20%, particularly preferably less than 10%, quite preferably less than 1%, and even more preferably less than 0.1%.

Without a barrier or frame, by means of which the process space is gas-tightly closed, there is, in the device according to invention between the edges of the surfaces to be processed of the two substrates opposite each other, an opening (a gas passage opening) of the process space. This opening has, depending on the distance d between the two substrates, a certain opening area S. In the case of rectangular substrates with edge length a and b that are positioned at a distance d (distance between the two surfaces to be processed, that are opposite each other in the multilayer body arrangement), the opening area S at the substrate edges is indicated by the formula S=(2·a+2·b)·d. On the other hand, a total processing area T on the two substrates, consisting of the coated surfaces of the two substrates, is processed in the process space. The total processing area T is indicated by the formula T=2·a·b (two rectangular, coated substrates of edge length a and b). Considering the relationship of opening area S to the total processing area T (specified as A=S/T), it is advantageous in the multilayer body arrangement according to the invention for A to have a maximum value of 0.4, preferably a maximum value of 0.2, particularly preferably a maximum value of 0.02, and even more preferably a maximum value of 0.002.

Provision is thus now made according to the invention that at least two substrates are processed at the same time in a substantially vertical alignment, by means of which the processing of the two substrates occurs jointly in a common process area using at least one process tool. In the context of a combinatorial effect, for one thing, a largely stress and bending free mounting of the substrates is enabled. Whereas with horizontal processing, in particular also with such processing with a process box, the substrate had to be supported against bending on a large number of support points; with vertical processing, it is possible to do without support elements that act on the inner substrate surface. Such support points acting on the inner substrate surface result, in fact, for one thing, in tensions and, for another, they cause shadowing effects. These shadowing effects arise not only with coating procedures, but also, especially, with tempering, since the support points modify the temperature profile locally in the substrate. Because of the fact that now no support points have to be provided on the inner substrate surface, such tensions and bending in the substrate are prevented and, also, shadowing effects no longer occur. Another advantageous effect of the design according to the invention consists in that now two substrates can be processed at the same time in relation to one process tool, doubling the throughput of such a vacuum treatment system, resulting in a significant cost reduction.

In a preferred embodiment, a substrate transport device is provided that is adapted to transport the substrates through the device past the process tool. The device is particularly simply structured from a design standpoint. Moreover, through the connection one after another of a plurality of such devices, it is possible to construct an in-line vacuum processing system in a simple manner with which many substrates can be processed consecutively in different process stations. Alternatively or additionally, it can, however, also be advantageous to provide a process tool transport device adapted to transport the process tool through the device past the substrates.

The process tool is expediently disposed between the two substrate levels. Then, it acts equally and particularly effectively on both substrate levels and the substrates situated there. It is, however, also possible in the case of a heat source as a process tool that it be disposed outside the two substrate levels. Thus, particularly effective and gentle tempering occurs since the heat source does not have to be disposed in the immediate proximity of the coatings and, nevertheless, especially with thin substrates, very homogeneous tempering can occur since each substrate is also heated indirectly by the substrate opposite it.

Particularly advantageously, the substrate levels, preferably the substrate transport device, have rolling elements that are adapted to support the substrate, wherein the rolling elements are preferably implemented with a groove shape to thus form a guide channel for the substrate.

Furthermore, at least one gas inlet can expediently be provided in the process area.

In a preferred embodiment, at least one basin that is preferably implemented to be extractable from the device is disposed below the substrate levels. This basin can catch material that is created in the event of a possible substrate breakage such that this material can be readily taken out of the device.

Independent protection is claimed for a method for processing substrates, in particular coated substrates, in a processing system, preferably a vacuum treatment system, with at least one process tool disposed in at least one process area, in particular a thermal evaporator device, a sputtering device, preferably a rotatable cylinder magnetron sputtering device, a heating device, or the like, wherein at least two substrates are disposed in the process area in substrate levels disposed opposite each other, wherein the substrate levels are aligned substantially vertical, wherein the substrate levels are preferably aligned in parallel relative to their vertical components. Preferably, this method is carried out in a device as is described above. The substrates have coatings and the substrates are in each case disposed opposite each other such that the coatings of the substrates face each other. Thus, a spatially very small process space is defined. This process space can preferably be defined even smaller in that, at least during processing, a closed process space is formed between the substrates, in particular by arranging a frame between the substrates.

Provision is made in an expedient embodiment that a carrier gas and/or process gas is introduced between the substrate levels, wherein, preferably in the frame, at least one gas inlet and at least one gas outlet are provided. The process space is closed except for the gas inlet and the gas outlet. Advantageously, the substrates are moved past the process tool, with the process tool alternatively or additionally also moved past the substrates.

The invention further extends to the use of a device as described above as well as a method as described above for production of a thin-film solar cell or module that preferably contains, as a semiconductor layer, a chalcopyrite compound, in particular Cu(In,Ga)(S,Se)₂. Preferably, the use serves to produce a CIS or (CIGSSe) thin-film solar cell or a CIS or (CIGSSe) thin-film solar module, wherein, in particular, each substrate is implemented in the form of a glass pane and is coated with at least the elements Cu, In or Cu, In, Ga or Cu, In, Ga, selenium for selenization and/or sulfurization of a chalcopyrite thin-film semiconductor.

It is understood that the various embodiments of the objects of the invention can be realized individually or in any combinations. In particular, the above mentioned characteristics and those to be explained in the following can be used not only in the combinations indicated but also in other combinations or alone, without departing from the framework of the present invention.

In the following, the invention is described with reference to exemplary embodiments that are explained in detail with reference to the drawings. They depict:

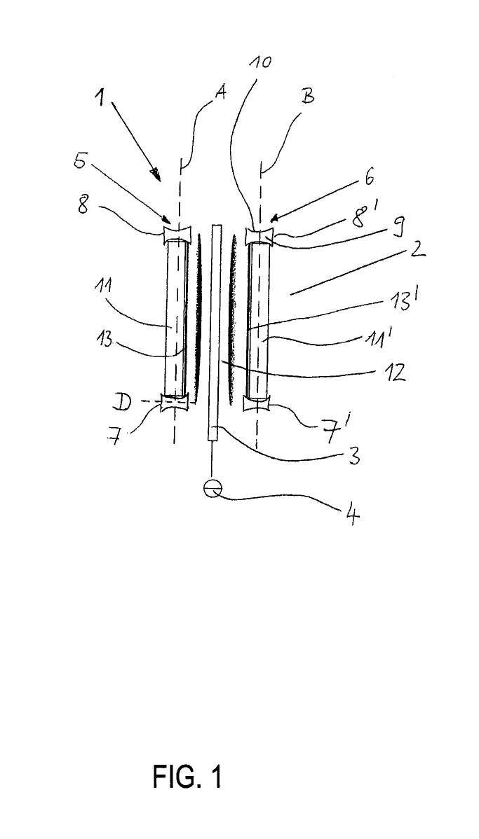

FIG. 1 the device according to the invention in a first preferred embodiment, and

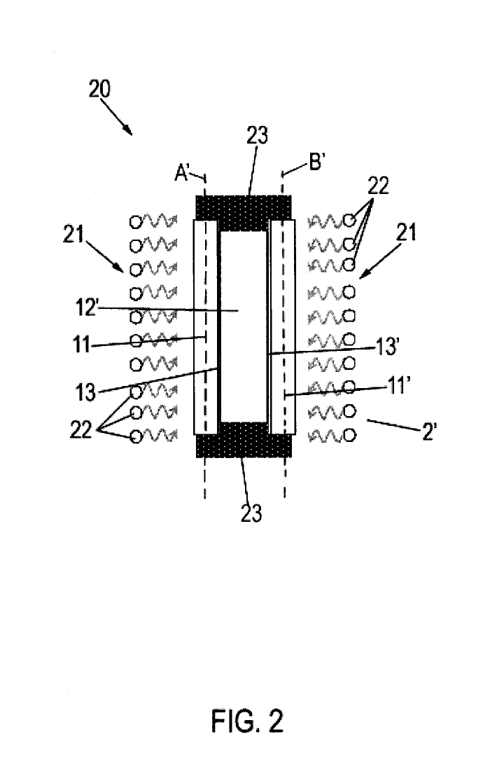

FIG. 2 the device according to the invention in a second preferred embodiment.

FIG. 1 depicts, purely schematically, the device 1 according to the invention in a first preferred embodiment in cross-section. The device 1 has an evacuable housing (not shown) in which a specific pressure level can be set by means of suitable pump technology.

In a process area 2 of the device 1, at least one process tool 3 is disposed, which is implemented in the present case as a rotatable cylinder magnetron sputtering device 3, which is well known to the person skilled in the art. This sputtering device 3 is connected to an electrical supply device 4, which is situated outside the housing of the device 1.

On both sides of the sputtering device 3, two substrate transport devices 5, 6 are provided in the device, wherein each transport device 5, 6, respectively, is formed by a lower row 7, 7′ and an upper row 8, 8′ of rolling elements 9 disposed horizontally in a plane. The lower row 7, 7′ and the upper row 8, 8′ are disposed substantially vertically one above the other such that by means of the two transport devices 5, 6 substantially vertically running substrate levels A, B are defined. The rolling elements 9 are mounted rotatably around the axis D and have, relative to their longitudinal direction along the axis D, a concave curvature, by which a guide channel 10 is formed, in which the substrates 11, 11′ can be disposed.

The substrates 11, 11′ are transported via the rolling elements 9 in a plane vertical to the plane of the drawing along the substrate levels A, B past the sputtering device 3, wherein, in the context of an in-line treatment method, additional processing steps can be connected upstream and/or downstream from the coating process by means of the sputtering device 3, for example, tempering steps and the like.

A quasi-closed process space 12 that is bounded on the sides by the substrates 11, 11′ is formed between these substrates 11, 11′. For this purpose, the two substrates 11, 11′ disposed in parallel have a distance between them of, for example, 5 mm. The substrate area of the rectangular substrate is, for example, 500 cm².

Also, optionally, upper and lower boundaries, roughly at the height of the rolling elements 9, can be provided to delimit the process space 12. Via suitable gas inlet and gas outlet elements (not shown), a process gas is admitted into the process space 12 during the coating, by means of which a sputtering process, for example, a reactive sputtering process, is carried out in the process space 12 by means of the sputtering device 3 in order to provide the substrates 11, 11′ with a coating 13, 13′.

Because of the fact that the two substrates 11, 11′ are disposed with their sides to be coated facing each other and delimit a shared process space 12, the coating of the substrates 11, 11′ with the coating 13, 13′ can take place with one shared sputtering device 3, as a result of which, for one thing, the throughput is doubled compared to single processing lines and, for another, compared to the use of two sputtering devices, significantly less process gas is required. Moreover, it is possible to do without the use of process boxes or the like for reduction of the process space 12, because the substrates 11, 11′ themselves now delimit the process space 12. Through the arrangement of the substrates 11, 11′ in vertical substrate levels A, B, it is also accomplished that the substrates 11, 11′ are subjected to no support-related tensions and shadowing effects. Thus, the application of the coating 13, 13′ is very homogeneous. Possible temperature-related size changes in the substrates 11, 11′ are dissipated via the rotatable rolling elements 9 such that, during the processing, there is no warping of the substrates.

FIG. 2 depicts, purely schematically, a second preferred embodiment of the device 20 according to the invention in cross-section, wherein, again, the walls of the device 20 and other nonessential elements are not shown. The substrate transport device is also not shown here. The same and like elements are provided with the same and like reference characters.

It can be seen that here, again, substrates 11, 11′ provided with coatings 13, 13′ are disposed in two substrate levels A′, B′ disposed opposite each other. The substrates are, in turn, aligned with their sides to be coated facing each other and they define between themselves the process space 12′, in which, here, however, no coating tool or the like is disposed. Instead, the process area 2′ is set up for tempering, for which a heat source 21, consisting of numerous heating elements 22 is provided. The heat source is, to be sure, disposed outside the two substrate levels A′, B′ in two rows of heating elements 22, but this is a single process tool 21, since, for one thing, the heating elements 22 are operated together and, for another, the heating elements 22 disposed in the substrate level A′ on the substrate 11 also indirectly heat the other substrate 11′ in the substrate level B′ and vice versa.

Since with this advantageous device 20 for tempering, the substrates 11, 11′ are again disposed facing each other and delimit a shared process space 12′, the tempering process can be executed very effectively and also cost-effectively because, for one thing, at least these two substrates 11, 11′ can be tempered at the same time, and, for another, to prevent escape of volatile components, it is necessary to introduce an excess of the volatile components only in this limited process space 12′, and this excess is used at the same time for both substrates 11, 11′.

The process space 12′ can additionally be delimited and gas-tightly closed in that, between the substrates 11, 11′, a gas-tight frame 23 is provided, which extends along breadth of the substrates 11, 11′. This frame 23 can, for example, be disposed stationarily in the device 20, wherein the substrates 11, 11′ are guided past this frame with a very small gap between them by means of the substrate transport device (not shown). Alternatively, the frame 23 can be moved along with the two substrates 11, 11′ and can, in particular, also be attached thereto. The gas inlet and gas outlet elements can also be disposed in this frame 23. As shown in FIG. 2, provision is not made with the use of such a frame 23 that a process tool be situated between the two substrates 11, 11′.

Whereas, in the case of the preferred embodiments, passage of the substrates 11, 11′ past the process tools 3, 21 was always assumed; provision can, of course, also be made for the substrates to be disposed stationarily and the process tools to be guided past the substrates.

Further optimization could also be undertaken in that in the context of an in-line vacuum treatment system, the substrates are successively guided through different process areas 2, 2′, wherein during processing of two substrates 11, 11′ in, for example, a coating area, the coating tool 3 is also moved in a specific manner inside the process area 2, in order to set specific coating parameters to be achieved.

The device 1, 20 can be used in any processing systems, but is preferably used in vacuum treatment systems to enable treatment under special process atmospheres. Treatment can, of course, also be carried out under atmospheric pressure or even under overpressure in order, for example, to perform a heating process under specially adapted conditions.

From the above presentation, it is clear that with the device 1, 20 according to the invention and the method according to the invention, substrate processing that is substantially more efficient and more cost effective is possible, and, moreover, enables very homogeneous processing.

In the following, further aspects of the invention are described:

The invention relates to a device for processing substrates, in particular coated substrates, in a processing system, preferably a vacuum treatment system, with at least one process tool disposed in at least one process area, in particular a thermal evaporator device, a sputtering device, preferably a rotatable cylinder magnetron sputtering device, a structuring device, a heating device, or the like, which is distinguished in that it has two substrate levels disposed opposite each other in the process area, which are aligned substantially vertical, such that the device is adapted to process at least two substrates at the same time in the process area by means of the process tool, wherein the substrates can be disposed in the substrate levels, and wherein the substrate levels are preferably aligned in parallel relative to their vertical components. According to one embodiment, a substrate transport device is provided that is adapted to transport the substrates through the device past the process tool, and/or a process tool transport device is provided that is adapted to transport the process tool through the device past the substrates. According to one embodiment, the process tool is disposed between the two substrate levels, and/or the process tool is a heat source that is disposed outside the two substrate levels. According to one embodiment, the substrate levels, preferably the substrate transport device, have rolling elements that are adapted to support the substrate, wherein the rolling elements are preferably implemented with a groove shape to thus form a guide channel for the substrates. According to one embodiment, at least one gas inlet is provided in the process area, and/or at least one basin that is preferably implemented to be extractable from the device is disposed below the substrate levels. According to one embodiment, a frame is disposed between the substrate levels.

A method according to the invention for processing substrates, in particular coated substrates, in a processing system, preferably a vacuum treatment system, with at least one process tool disposed in at least one process area, in particular a thermal evaporator device, a sputtering device, preferably a rotatable cylinder magnetron sputtering device, a heating device, or the like, is distinguished in that at least two substrates are disposed in the process area in substrate levels disposed opposite each other, wherein the substrate levels are aligned substantially vertical, wherein the substrate levels are preferably aligned in parallel relative to their vertical components, wherein the method is, in particular, carried out in a device as is described above. According to one embodiment, the substrates have coatings and the substrates are in each case disposed opposite each other such that the coatings of the substrates face each other, wherein, preferably, at least during processing, a substantially closed process space is formed between the substrates, in particular by arranging a frame between the substrates. According to one embodiment, a carrier gas and/or process gas is introduced between the substrate levels, wherein, preferably in the frame, at least one gas inlet and at least one gas outlet are provided. According to one embodiment, the substrates are moved past the process tool, and/or the process tool is moved past the substrates.

1. A device comprising:
a process tool disposed in a process area;
two substrate levels disposed opposite each other in the process area, wherein the two substrate levels are aligned at least approximately vertical,
wherein the device is adapted to process at least two substrates at the same time in the process area with the process tool, wherein the substrates are disposed in the two substrate levels such that a coating on each of the substrates faces the other and, at least during processing, a quasi-closed process space is formed between the substrates.

2. The device of claim 1, wherein the substrate levels are aligned in parallel relative to their vertical components.

3. The device of claim 1, further comprising:
a frame disposed between the substrates to form a closed process space.

4. The device of claim 1, further comprising:
a substrate transport device, which transports the substrates through the device, past the process tool; and/or
a process tool transport device, which transports the process tool through the device past the substrates.

5. The device of claim 1, wherein the process tool is disposed between the two substrate levels (A, B) and/or the process tool is a heat source that is disposed outside the two substrate levels.

6. The device of claim 4, wherein the two substrate levels have comprise a rolling element, which supports the substrate.

7. The device of claim 6, wherein the substrate transport device comprises the rolling element.

8. The device of claim 6, wherein the rolling element comprises a groove shape, and the groove shape forms a guide channel for the substrate.

9. The device of claim 1, further comprising:
a gas inlet in the process area and/or a basin disposed below the substrate levels.

10. The device of claim 1, wherein further comprising:
a frame disposed between the two substrate levels.

11. A method for processing coated substrates, the method comprising:
processing at least two substrates comprising a coating with a process tool in a processing system,
wherein the process tool is disposed in a process area, wherein coated substrates are disposed in the process area in two substrate levels disposed opposite to each other, and the substrate levels are aligned at least approximately vertical,
wherein the coated substrates the substrates are disposed opposite to each other such that each coating of the substrates faces the other, and
wherein, at least during processing between the substrates, a quasi-closed process space is formed between the substrates.

12. The method of claim 11, wherein a frame is disposed between the coated substrates to form a closed process space.

13. The method of claim 11, further comprising:
introducing a carrier gas and/or a process gas between the substrate levels.

14. The method of claim 11, further comprising:
moving the substrates are moved past the process tool and/or moving the process tool past the substrates.

15. The method of claim 11 wherein, each substrate is implemented in the form of a glass pane and is coated with at least the elements Cu, In or Cu, In, Ga or Cu, In, Ga, selenium for selenization and/or sulfurization of a chalcopyrite thin-film semiconductor.
